(19) United States
(12) Patent Application Publication
(10) Pub. No.: US 2008/0062017 A1
(43) Pub. Date: Mar. 13, 2008

(54) DEBOUNCING CIRCUIT

(75) Inventor: Rob Macaulay, Cambridge (GB)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(73) Assignee: GS IP Limited Liability Company, Wilmington, DE (US)

(21) Appl. No.: 11/779,205

(22) Filed: Jul. 17, 2007

(30) Foreign Application Priority Data
Jul. 18, 2006 (GB) 0614259.0

(51) Int. Cl. H03K 17/94

(52) U.S. Cl. 341/24

(57) ABSTRACT

A switch circuit comprising a mechanical switch having two contact elements, the switch being operable to bring the two contact elements into physical contact and thereby output an analog switch signal representative of operation of the switch and a sigma-delta modulator arranged to receive the analog switch signal and to output a digital switch signal in dependence thereon, the sigma-delta modulator having a frequency response such that it can suppress a relatively high frequency component of the analog input signal and thereby effectively debounce the output of the switch.

### RELATED APPLICATIONS

This application claims the right of priority to United Kingdom Application No. GB 0614259.0, filed 18 Jul. 2006 (title: A DEBOUNCING CIRCUIT by applicant: Global Silicon Limited), which is hereby incorporated by reference herein.

### FIELD OF THE DISCLOSURE

The present disclosure relates to a debouncing circuit for removing high frequency oscillations in a switch output that may arise when contact is made and broken between two contact elements of the switch.

### BACKGROUND

Switches or keys are widely used as user input devices. Many switches are mechanical devices. In the simplest case, a switch consists of two pieces of metal called contacts that touch to make a circuit and separate to break a circuit. The actuator that applies the operating force to the contacts may be any type of mechanical linkage (e.g. a toggle, rocker or push button), or may arise automatically, as in a relay.

Simple metal contact switches include spring-loaded keys that have plungers with a strip of metal on their underside for contacting two parts of a circuit. In a variation, a small piece of foam may be placed between the bottom of the plunger and the metal strip. Such switches have the advantages of providing a good tactile response and being inexpensive to produce. However, the contacts tend to wear out or corrode quite quickly. Other switches include rubber dome switches and membrane switches.

Rubber dome switches use small, flexible rubber domes that have a hard carbon center. When a key is pressed, a plunger on the bottom of the key pushes down against the dome and causes the carbon center to press against a surface beneath the key. While the key is pressed, the carbon center completes the surface. When the key is released, the dome springs back to its original position and the circuit is broken. Rubber dome switches also provide a reasonable tactile response and are inexpensive.

Membrane switches are typically used for keypads or keyboards. Rather than having a switch for each key, they use a continuous membrane having a pattern printed on it that completes a circuit when a key is pressed. Some membrane keyboards use a flat surface printed with representations of each key rather than using separate key heads for individual keys. Membrane keyboards do not have a good tactile response, but they are generally inexpensive.

Switches are often grouped together to form keypads or keyboards having multiple switches. Rather than having each key or switch connected to an individual wire, keyboards are typically arranged so that the keys or switches are connected in rows and columns to form a matrix. In order to detect key presses, the keyboard typically ‘scans’ the matrix by activating each column in turn and then detecting which rows are activated. A column is activated by passing an electric current through it. A key press is detected when an electric current is output by a row. When a column is activated and an electric current is output by one or more of the rows, this indicates that a key located at the intersection between that column and the one or more rows has been pressed. A simple key matrix is shown in FIG. 1.

A problem arises when the keys are mechanical devices, as such devices tend to be subjected to contact bounce (or chatter) when the contacts are forced together or when they separate. Contact bounce is caused by the momentum and elasticity of the contacts and results in a rapidly pulsed electrical current, as shown in FIG. 2. This high frequency oscillation causes problems because it can be detected by the keyboard controller and results in so-called ‘false-triggering’, in which the keyboard controller detects multiple key strokes from a single key depression by the user. The signal output from a mechanical switch is therefore typically passed through a ‘debouncing’ circuit to remove this high frequency chatter.

A debouncing circuit is a circuit that receives an input switch signal containing high frequency chatter superimposed on a lower frequency keying signal. The role of the debouncing circuit is to remove the high frequency chatter while retaining the lower frequency keying signal.

A simple debouncing circuit is shown in FIG. 3. The circuit comprises a resistor 301 and a capacitor 302. The debouncing circuit is a simple RC circuit that acts as a low pass filter and thereby removes the high frequency chatter from the switch output. The resistance and capacitance values are chosen to give an appropriate frequency response for expected keying and chatter frequencies. The problem with this circuit is its slow response. Some key presses may therefore not be represented in the ‘debounced’ output signal.

An improved debouncing circuit is shown in FIG. 4. This circuit comprises two NAND gates 401, 402 arranged as a ‘set-reset’ flip-flop 403. The debounced signal is output at node 404. This circuit successfully removes high frequency chatter from the switch signal, has a fast response and outputs a digital signal suitable for supplying to a keyboard controller. This circuit does however have the disadvantage that it can only receive and successfully debounce a single switch. For switches that are arranged in key matrices, therefore, a separate debouncing circuit is provided for each switch. Typically, the switch debouncing circuitry is to be hardwired into the matrix circuit. This is costly and uses valuable space.

The current signal may be advantageously detected by passing it through an impedance, such as a potential divider, so that signal of varying amplitude is output by each row of the matrix as the keyboard sequentially activates each of the columns. This signal therefore represents the status of each of the keys of the keyboard scanned from one end of the keyboard to the other. If the signal has previously been debounced, then the varying signal is typically input into a keyboard controller, which analyzes the analog signal to determine which of the keys have been depressed and outputs the resulting data to an overall controller (e.g. such as the operating system of a computer).

One alternative to debouncing each switch individually in hardware is to debounce a switch signal in software. However, this requires a software controlled processor to be provided in the neighborhood of the keyboard or keypad in whatever device the keyboard or keypad has been incorporated into. This is problematic in space-limited implementations. For example, portable audio players such as MP3 players often have a small user input device incorporating switches located on a lead between the device and a set of headphones. With such small user input devices, it would be preferable if debouncing of the switches could be performed in hardware within the device itself before the final switch signal is transmitted over the lead to the portable media player.

There is therefore a need for an improved circuit for debouncing a switch signal.

### BRIEF DESCRIPTION OF THE DRAWINGS

For a better understanding of the present disclosure, reference is made by way of example to the following drawings, in which:

FIG. 1 shows a switch matrix;

FIG. 2 shows a switch signal exhibiting chatter;

FIG. 3 shows a simple debouncing circuit;

FIG. 4 shows a debouncing circuit including a ‘set-reset’ flip-flop;

FIG. 5 shows a switch matrix in which each switch causes a different voltage level to be output from the matrix when it is depressed;

FIG. 6 shows a debouncing circuit;

FIGS. 7a-c show the effect of oversampling and digital filtering on the output noise level of an ADC;

FIGS. 8a-b show the effect of noise shaping on the output noise level of an ADC;

FIG. 9 shows an overview of the stages involved in reducing noise levels in the output signal;

FIG. 10 shows the effects of decimation on noise reduction;

FIG. 11 shows a sigma-delta modulator;

FIG. 12 shows waveforms for implementing a gain function in a sigma-delta modulator;

FIG. 13 shows waveforms for implementing a gain function in a sigma-delta modulator;

FIG. 14 shows a further sigma-delta modulator; and

FIG. 15 shows a representation of the elements contributing to a sigma-delta modulator's frequency response.

### DETAILED DESCRIPTION

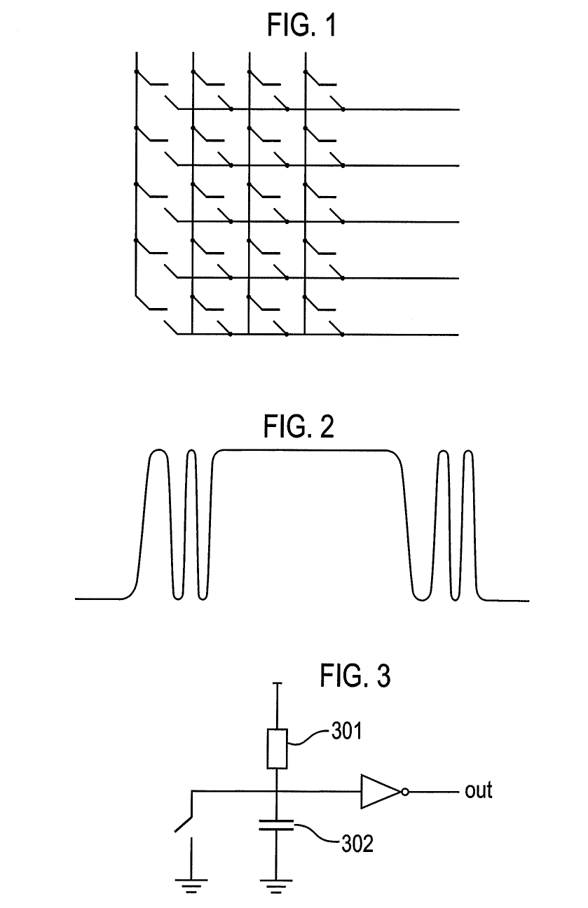

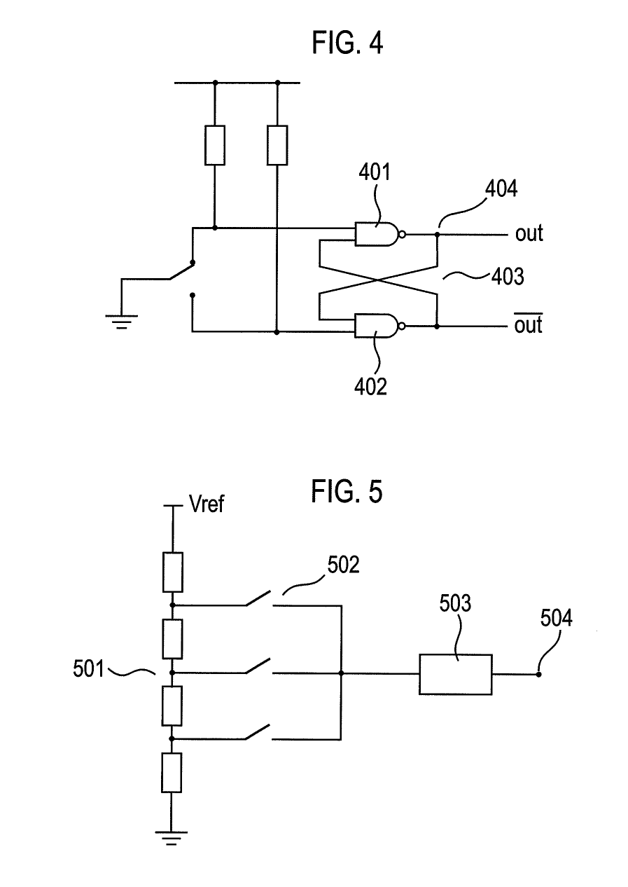

An alternative switch matrix to that illustrated in FIG. 1 is shown in FIG. 5. This switch matrix is arranged as a potential divider 501, with each switch 502 being located at a different level in the divider. In a switch matrix according to this arrangement, each switch causes a different voltage to be output from the matrix when it is depressed. Therefore, a depressed switch can be identified by the voltage output by the matrix. If the switches are mechanical, then they need to be debounced as described above. This form of switch matrix has the additional requirement that any debouncing process must preserve the difference between the signals output by each switch, so that the different switches can still be identified.

According to a first aspect of the disclosure, there is provided a switch circuit comprising a mechanical switch having two contact elements, the switch being operable to bring the two contact elements into physical contact and thereby output an analog switch signal representative of operation of the switch and a sigma-delta modulator arranged to receive the analog switch signal and to output a digital switch signal in dependence thereon, the sigma-delta modulator having a frequency response such that it can suppress a relatively high frequency component of the analog input signal and thereby effectively debounce the output of the switch.

The switch circuit may comprise a plurality of mechanical switches and the switch circuit is arranged such that a single analog switch signal representative of the operation of each of the plurality of switches is output by the plurality of switches and received by the sigma-delta modulator.

The switch circuit may comprise an array of switches extending in two dimensions, each switch being located on a row in the first dimension and a column in the second dimension and each row of the array being arranged to output a single analog switch signal representative of the operation of each of the switches located in that row.

The switch circuit may be arranged to sequentially activate each column of the array by applying an electric current to each column in turn, the instantaneous value of the single analog switch signal output by a row of the array being representative of the operation of a switch located in the currently activated column of that row.

The switch circuit may be arranged such that operation of one of a plurality of switches causes the single analog switch signal to have a specific voltage level. The specific voltage level may be the same irrespective of which switch has been operated. Alternatively, the specific voltage level is dependent on which switch has been operated.

Each switch located in a row of the array may be associated with a specific voltage level such that operation of a switch in that row causes the single analog switch signal to have the specific voltage level associated with the operated switch. A row of the array may comprise a potential divider and each switch located in that row may be connected to a specific voltage level within the potential divider such that operation of a switch causes the single analog switch signal to have the specific voltage level connected to the operated switch.

The sigma-delta modulator may comprise a summation unit for summing the analog switch signal with an adjustment signal to form a summation output signal, an integrator arranged to receive the summation output signal and form an integrator output signal dependent thereon, a quantizer arranged to receive the integrator output signal and form the digital switch signal dependent thereon and a feedback loop for generating the adjustment signal.

The feedback loop may comprise a digital-to-analog converter for receiving the digital output signal and generating the adjustment signal in dependence thereon.

The feedback loop may comprise a logic circuit arranged to select between one of two predetermined values for the adjustment signal, the selection being performed in dependence on both the digital output signal and a control signal.

The feedback loop may comprise a selection circuit arranged to select between one of two boundary values for the adjustment signal, the selection being performed in dependence on the digital output signal.

The sigma-delta modulator may be arranged to sample the analog input signal at a sampling rate that exceeds a maximum frequency of operation of the mechanical switch by a user. The operation of the mechanical switch is suitably the activation of the switch so as to bring the two contact elements into physical contact. The sampling rate may exceed 20 Hz.

The sigma-delta modulator may be arranged to receive a clock signal of 5.12 kHz or above.

The sigma-delta modulator may be configured to low-pass filter the analog switch signal.

The sigma-delta modulator may have a frequency response such that it can suppress the relatively high frequency component of the analog input signal relative to a lower frequency component of the analog input signal that is representative of operation of the mechanical switch by a user.

According to a second aspect of the disclosure, there is provided a use of a sigma-delta modulator to debounce an output of a mechanical switch.

A switch circuit comprises a mechanical switch and a sigma-delta modulator for debouncing the switch output. The sigma-delta modulator is capable of converting the analog signal output by the mechanical switch into a digital signal. The frequency response of the sigma-delta modulator may be such that it removes any high frequency chatter component from the switch output (e.g. by low-pass filtering the analog switch signal).

A sigma-delta modulator is capable of receiving a continuous analog input signal and of continuously debouncing that input signal. This has the advantage that a separate debouncing circuit need not therefore be provided for every switch. Instead, multiple switches can be debounced by a single sigma-delta modulator. This can be achieved by forming a single analog input signal representative of the status of multiple switches and inputting this signal into the sigma-delta modulator. For example, the sigma-delta modulator may receive an analog switch signal that is generated by a row of switches in a switch matrix. Such a signal can be formed, for example, by a key scanning keyboard such as that shown in FIG. 1 and described above, in which each column of a switch matrix is activated in turn.

The current signal output by a row of a switch matrix such as that illustrated in FIG. 1 may be advantageously detected by passing it through an impedance, such as the potential divider. This generates an analog switch signal of varying amplitude that is output by each row of the matrix as the keyboard sequentially activates each of the columns. This analog signal therefore represents the status of each of the keys of the keyboard scanned from one end of the keyboard to the other. This signal can the be input into a sigma-delta modulator to be digitized and debounced.

A sigma-delta modulator is also advantageous in switch matrices such as the one illustrated in FIG. 5, in which activation of each switch causes a different voltage to be output from the matrix. In FIG. 5, the sigma-delta modulator 503 is arranged to receive the output of the switch matrix, which will vary in amplitude depending on which of the switches has been operated. This variation in voltage level can be used to identify which of the switches has been operated. Because the sigma-delta modulator is effectively an analog-digital-converter, the digital switch signal output at node 504 is representative of the voltage level of the analog switch signal. Thus, the sigma-delta modulator debounces the switch output while preserving its ability to identify the switches that have been activated.

Different implementations of sigma-delta modulators that are suitable for being used as debouncing circuits will now be described. These specific implementations are given for the purposes of example only and it should be understood that the disclosure is not limited to any specific implementation of a sigma-delta modulator.

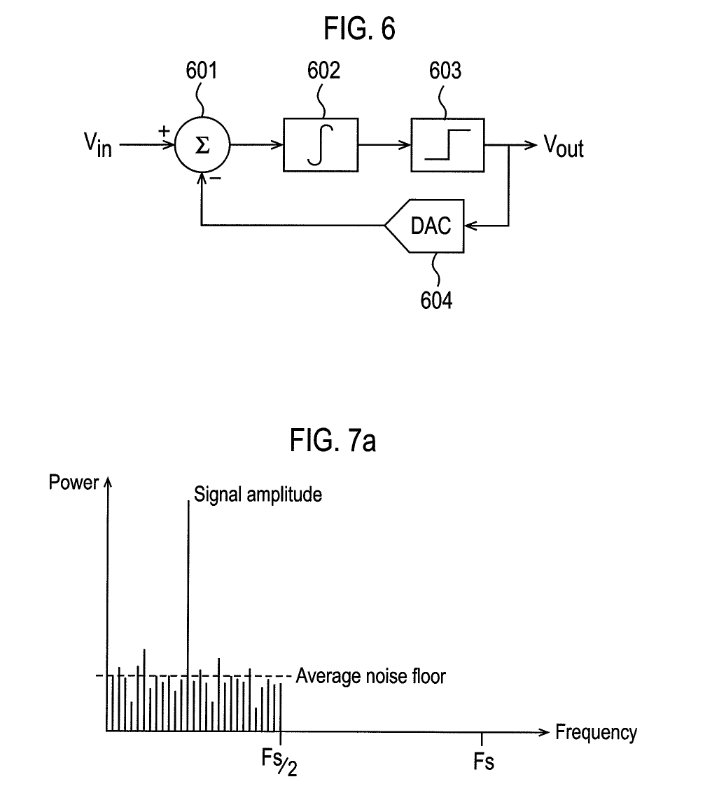

The operation of a sigma-delta modulator is best described using the simplest 1-bit implementation. A 1-bit sigma-delta modulator is illustrated in FIG. 6.

In the basic implementation illustrated in FIG. 6, the sigma-delta modulator comprises a summation unit 601, an integrator 602, a comparator 603 and a digital-to-analog converter (DAC) 604. The summation unit may be, for example, a difference amplifier. The comparator may be an analog-to-digital converter (ADC).

As can be seen in FIG. 6, the components of the modulator are connected in a feedback loop. The analog input signal is fed into the summation unit, where a feedback signal is subtracted, before being fed into a loop filter, which in this case is an integrator. The signal output from the integrator is compared with a reference signal in the comparator. If the output signal from the integrator is greater than the reference signal, a ‘one’ is output, and if the integrator output signal is less than the reference signal, a ‘zero’ is output. Thus the analog input signal has been converted into a digital output signal.

The digital output signal is fed back, via the DAC, to the summation unit, where it is subtracted from the input signal. The purpose of the feedback signal is to maintain the average output of the integrator near the comparator's reference level by making the ones and zeros of the digital output signal representative of the analog input.

The DAC in the feedback loop has an upper reference voltage and a lower reference voltage. When the comparator outputs a ‘one’, the DAC outputs a signal at the upper voltage and when the comparator outputs a ‘zero’, the DAC outputs a signal at the lower voltage. The modulator is at full-range scale when the input signal is equal to the upper or lower reference voltages of the feedback DAC. For example, if the feedback DAC outputs −2.5V when it receives a zero and 2.5V when it receives a one then the range of the input is ±2.5V. The reference voltage of the comparator is halfway between the upper and lower boundaries of the input range, e.g. for an input range of ±2.5V the reference voltage for the comparator would be 0V. The reference voltage for the comparator represents the virtual ground level for the modulator. For modulators having an input range that is symmetrical about zero, the virtual ground level is zero.

The output from the sigma-delta modulator is a stream of ones and zeros. The ratio of ones to zeros represents the magnitude of the input signal compared with the input range of the modulator. For example, if the range of the modulator is ±2.5V and the input signal has a magnitude of 1.0V, then the input signal is 3.5V above the lower boundary of a 5V range. In this example, 70% of the output signal should consist of ones. For the modulator to produce a digital output signal that is an accurate representation of the analog input signal, the modulator must sample at a much greater rate than the rate of change of the analog input signal.

More sophisticated sigma-delta modulators than the 1-bit modulator described above may have multiple modulators and integrators.

For a sigma-delta modulator as described herein, the component of the analog input signal to be converted into a digital output signal is the signal corresponding to operation of the switch(es) by a user. Therefore, in order for this switch or keying signal to be successfully converted to a digital output signal, the modulator must sample at a much greater rate than the rate at which the switch(es) can be expected to be operated by the user. Key presses by a user can be expected not to exceed 20 Hz (i.e. 20 key presses per second). The clocking frequency of the modulator is suitably at least S×F Hz, where S is the number of pulses that constitute a maximum measurement value and F is the sampling rate of the converter. The modulator is suitably clocked at at least 5.12 kHz. In practice, however, a much higher rate may be used.

A sigma-delta modulator may have a frequency response that successfully suppresses the high frequency chatter component of the switch output while retaining and successfully digitizing the part of the switch output representing activation and deactivation of the switch. The frequency response of the sigma-delta modulator is dependent on the exact implementation of the modulator. However, if the sigma-delta modulator is generally considered to consist of a loop filter having transfer function H(z) and a quantizing amplifier having gain g_{Q}, as shown in FIG. 15, then the signal transfer function is as follows:

$${H}_{X} ( z ) = \frac{Y ( z )}{X ( z )} = \frac{{g}_{Q} H ( z )}{1 + {g}_{Q} H ( z )} \\ where z = {ⅇ}^{j \frac{ω}{{ω}_{s}}} \qquad ( 1 )$$

By choosing an appropriate sampling frequency for a specific implementation of a sigma-delta modulator, the frequency response of the modulator can be chosen so as to preserve or amplify frequency components of the switch signal associated with operation of the switch and to remove frequency components associated with bouncing between the switch contacts. For a typical sigma-delta modulator, a suitable range for the sampling frequency is 0.4 to 4.0 kHz.

The noise transfer function for the quantization noise N(z) introduced by the quantizer is as follows:

$${H}_{N} ( z ) = \frac{Y ( z )}{N ( z )} = \frac{1}{1 + {g}_{Q} H ( z )} \qquad ( 2 )$$

Thus, if the modulator acts as a low pass filter to the input switch signal, it can be expected to act as a high pass filter to the quantization noise. This is described in more detail below.

A sigma-delta modulator offers improved noise performance over traditional ADCs. This is achieved through oversampling, noise shaping, digital filtering and decimation.

A traditional multi-bit ADC converts an analog signal into a digital signal by sampling the input signal at regularly spaced intervals in time and classifying the magnitude of the input signal as being one of a number of equally spaced, predetermined magnitudes. The simplest 1-bit ADC classifies the input signal according to two predetermined magnitude levels and the outputs either a one or a zero according to which of the two levels the input signal is closest to. Likewise, a 2-bit ADC classifies the input signal according to four predetermined levels and outputs either 00, 01, 10 or 11 during each sampling period and so on. The greater the number of magnitude levels to which the input signal is compared, the greater the resolution of the converter. By according the input signal one of an equally spaced number of values, the output of the ADC is inherently inaccurate. This is because the ADC input is a continuous signal with an infinite number of possible states while the output signal is a discrete function whose number of different states is determined by the converter's resolution. The conversion from analog to digital loses some information and introduces distortion into the signal. The magnitude of this error is random, with values up to ±LSB (the least significant bit of the digital output).

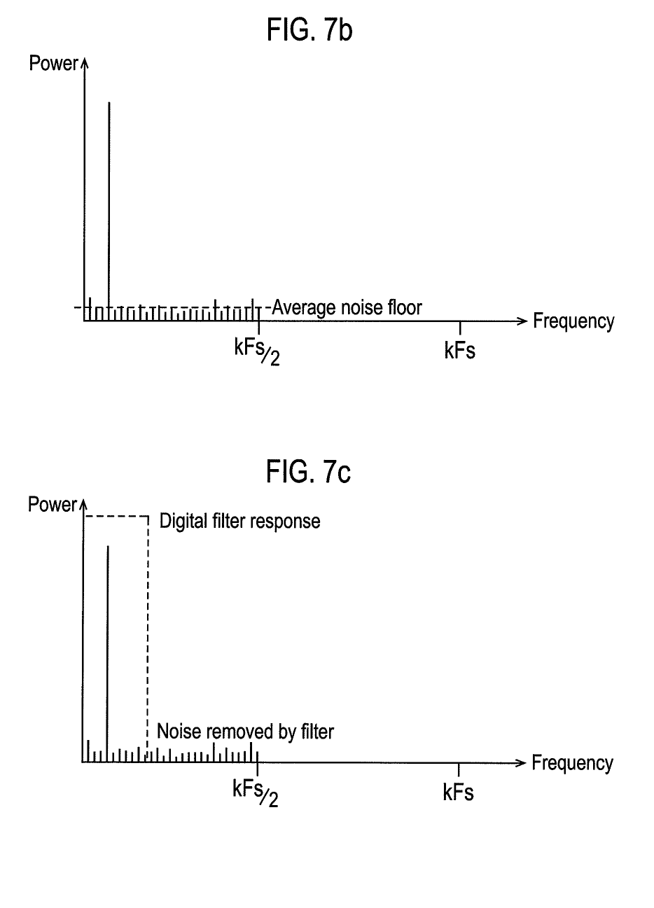

A typical graph that would be obtained from an FFT analysis of the output signal from a traditional multi-bit ADC with a sine-wave input signal is illustrated in FIG. 7a. Fs is the sampling frequency of the input signal, which must be at least twice the bandwidth of the input signal according to Nyquist theory. The FFT analysis breaks down the signal into its frequency components. The sine-wave is clearly visible as a large spike at a single frequency. However, lots of random noise is also visible extending from DC to Fs/2. This noise is a result of the distortion discussed above and is known as quantization noise.

The signal-to-noise ratio (SNR) is obtained by dividing the signal amplitude by the RMS sum of all the frequencies representing noise. In a conventional ADC the SNR can only be improved by increasing the resolution (i.e. the number of bits).

If the sampling frequency is increased by the oversampling ratio k, to kFs, the noise floor drops. This is illustrated in FIG. 7b. The SNR is unchanged from the situation in FIG. 7a, but the noise has been spread over a wider frequency range. Sigma-delta converters are able to exploit this effect by following the 1-bit ADC with a digital filter. The effect of the filter is illustrated in FIG. 7c. The RMS noise is less, because most of the noise passes through the digital filter. This action allows sigma-delta modulators to achieve a wide dynamic range from a low-resolution ADC.

However, the sigma-delta modulator cannot achieve a high resolution from oversampling alone as the oversampling ratio required for even a reasonable resolution is generally too high to be realizable. The sigma-delta modulator also shapes noise away from the peak gain response of the modulator.

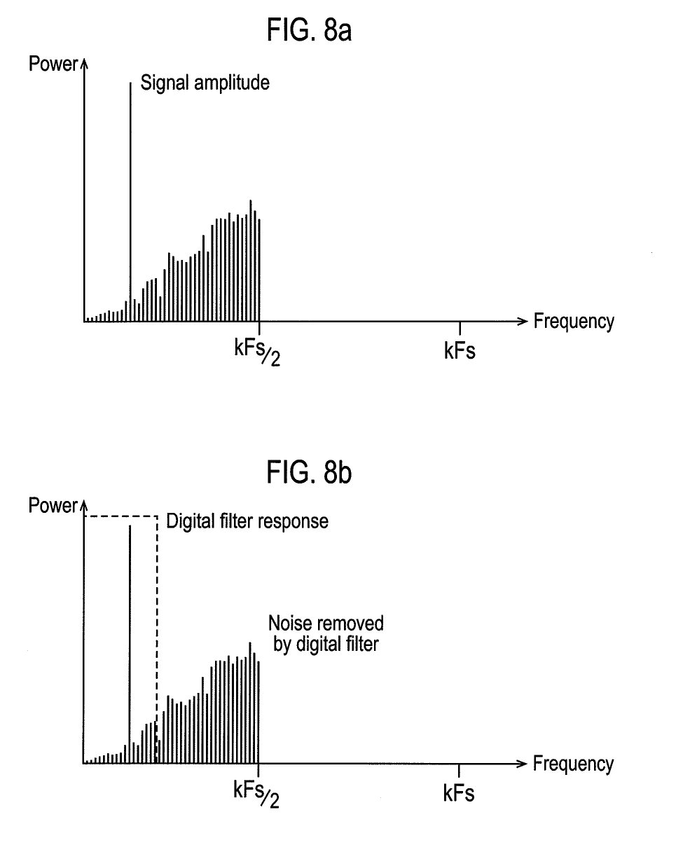

In the modulator illustrated in FIG. 6, the loop filter is an integrator, so the modulator shapes noise out of the lower frequencies and into the higher frequencies. This is because the integrator sums the error voltage, thereby acting as a low pass filter to the input signal and a high pass filter to the quantization noise. Thus, most of the quantization noise is pushed into higher frequencies (see FIG. 8a). Oversampling has not changed the total noise power, but its distribution.

For higher order sigma-delta modulators, noise shaping can be achieved by including more than one stage of integration and summation.

If a digital filter is applied to the noise-shaped output of the sigma-delta modulator, as illustrated in FIG. 8b, it removes more noise than does oversampling alone.

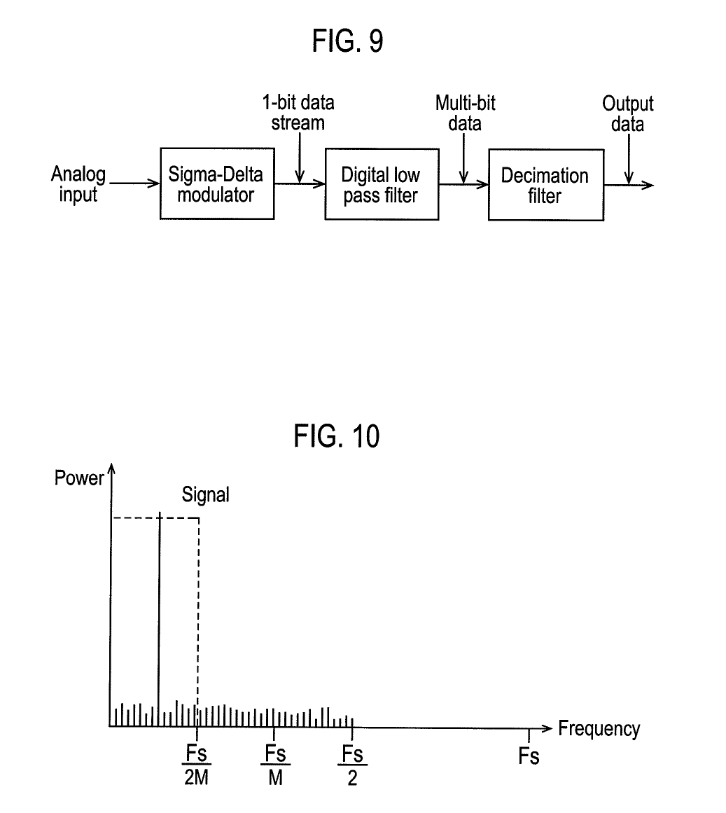

The output of the sigma-delta modulator is a stream of ones and zeros at the sampling rate. This data rate is usually very high, so a digital-and-decimation filter can be used to reduce the data rate to a more useful value. No useful information is lost during this process, as illustrated in FIG. 10. As the bandwidth of the signal is reduced by the digital output filter, the output data rate can satisfy the Nyquist criterion even though it is lower that the original sampling rate. This can be accomplished by preserving certain input values and discarding the rest. This process is known by decimation by a factor M (the decimation ratio). M can have any integer value, provided that the output data rate is more than twice the signal bandwidth. If the input has been sampled at Fs, the filtered-output data rate can be reduced to Fs/M without loss of information. The complete system, as described, above is illustrated in FIG. 9.

The sigma-delta modulator offers best resolution when the input signal varies between the upper and lower limits of the modulator's input range. The upper and lower limits can be considered as ±Vcc/2 about the virtual ground level of the modulator (i.e. the modulator has an input range of Vcc). One option for optimizing the resolution of the sigma-delta modulator is to implement a gain function in a sigma-delta modulator by introducing transition-cycles into the feedback path. Transition-cycles have a net average value equal to the virtual ground level of the modulator. By introducing more transition-cycles into the feedback path the overall average level of the feedback is reduced.

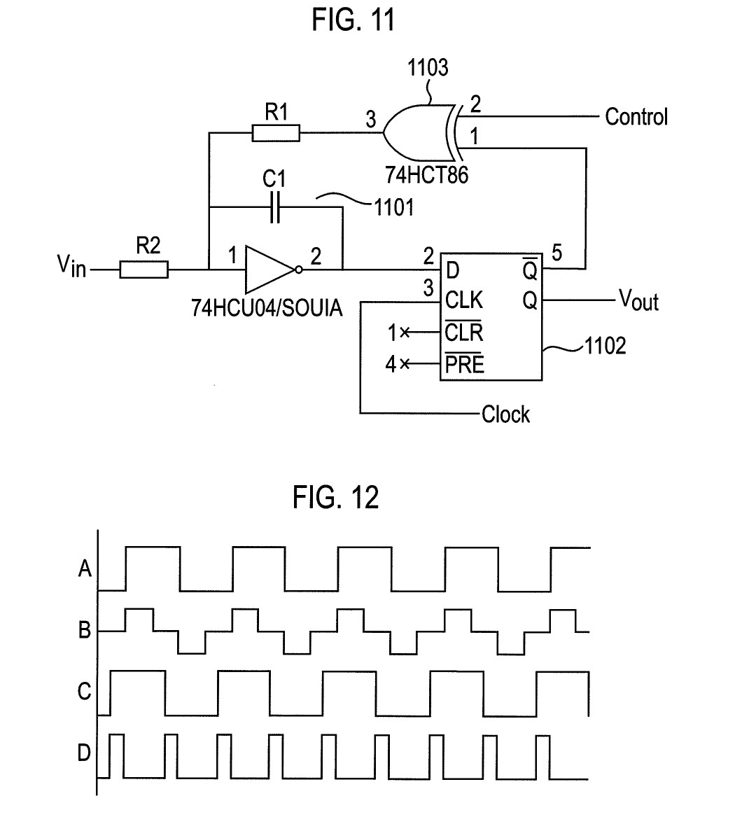

FIG. 11 illustrates a sigma-delta modulator that introduces transition-cycles into the feedback path. The loop filter 1101 is an integrator circuit, the quantizer is a latch 1102 and the feedback DAC has been replaced by an exclusive-OR gate (an XOR gate) 1103. The XOR gate has as its inputs the digital feedback signal and a control signal.

Waveform A of FIG. 12 shows a typical feedback signal for an input that is at the virtual ground level. In FIG. 12, the virtual ground level has been set at ½Vcc. The signal has a 50% duty cycle (i.e. half the cycles take the upper limit of Vcc and half the lower limit of 0V). The signal therefore represents an input having a magnitude that is midway between the upper and lower limits of the input range of the modulator (i.e. ½Vcc in this case).

Waveform B of FIG. 12 illustrates an equivalent feedback signal including transition-cycles. Waveform A, which is a non-return-to-zero or NRZ waveform, has been converted to a return-to-zero (RTZ) waveform. As can be seen from the figure, the transition-cycles have a net average value of ½Vcc (virtual ground).

Waveform B illustrated in FIG. 12 is difficult to directly synthesize. However, since the requirement for the transition-cycles is only that their net average value is equal to the virtual ground level, waveform C in FIG. 12 will have the same effect on the overall feedback level seen by the integrator as waveform B. In waveform C the transition-cycles have, in effect, been implemented as a pair of pulses, having an average value of ½Vcc.

Waveform C can be easily generated from waveform A by using an XOR gate with waveform D (also illustrated in FIG. 12). Therefore, in the sigma-delta modulator shown in FIG. 7, the digital output signal (waveform A) and the control signal (waveform D) are input into an XOR gate to create the feedback signal (waveform C). Note that the feedback signal still has a 50% duty cycle so the modulator is still balanced with an input of ½Vcc. In other words, for an input signal at virtual ground, the situation is unchanged by the introduction of transition-cycles into the feedback signal.

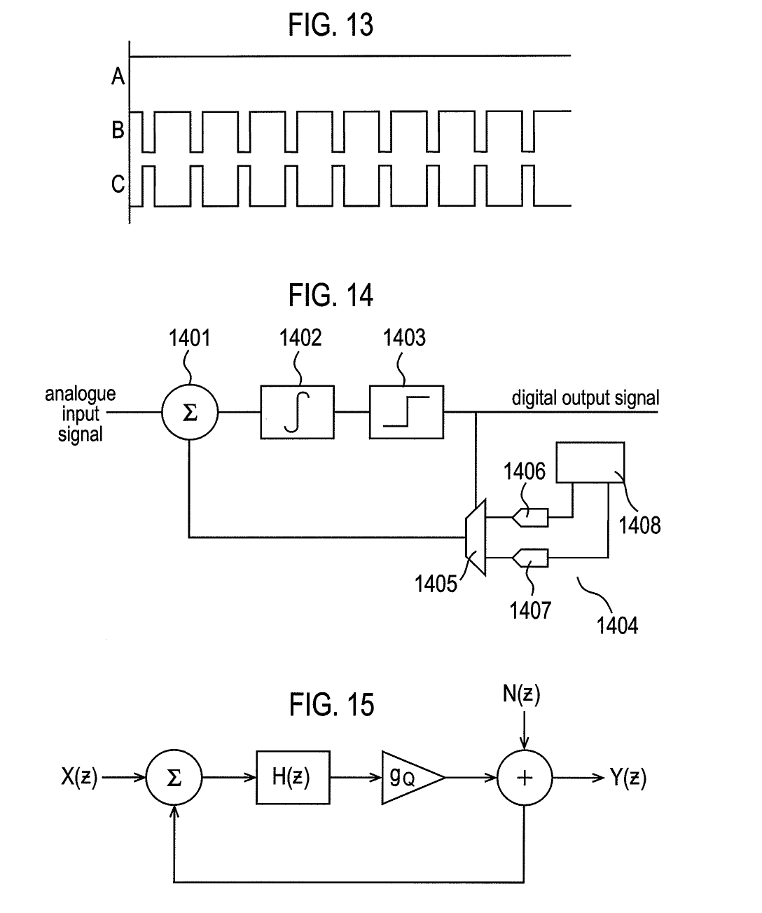

Waveforms A, B and C of FIG. 13 are similar waveforms for the situation where the modulator has a full scale positive input (Vcc). The digital output signal of the modulator is waveform A. As the input is at the upper limit, the output signal is always high (100% ones). If the same control signal (waveform C) were applied to the XOR gate along with the digital output signal, then the feedback waveform B is generated. This time, the feedback signal has a net DC content of ¾Vcc. Therefore, an input of ¾Vcc would be balanced by this feedback signal and the upper input limit to the modulator has been reduced by ¼Vcc.

Similarly, if the input to the modulator has a full scale negative input (0V), the same control signal would produce a feedback signal having a net DC content of ¼Vcc. Therefore, an input of ¼Vcc would be balanced by this feedback signal and the upper input limit to the modulator has been increased by ¼Vcc.

Therefore, overall, the waveform D of FIG. 12 and waveform C of FIG. 13 have managed to decrease the input range of the modulator from Vcc to ½Vcc. The modulator has an implied gain of two. By reducing the input range into the modulator by half, the control signal has effectively achieved the same result as an amplification by a factor of two prior to the sigma-delta modulator.

The control and feedback signals may have a higher frequency than the digital output signal. To achieve this, the XOR gate and the quantizer can receive different clock signals.

The control signal can also be used to apply an offset. This can be achieved using the same basic circuit as illustrated in FIG. 11. In this application, the control signal is arranged such that transition-cycles are injected into the feedback signal in an asymmetric manner. Replacing more ‘ones’ than ‘zeros’ in the output signal, causes the generated feedback signal to apply a positive offset to the input signal. This is because the net DC content of the feedback signal is decreased relative to the situation where the same number of transition-cycles is inserted into the feedback signal, but in a symmetric manner. Similarly, by replacing more ‘zeros’ than ‘ones’, a negative offset can be applied.

Introducing transition cycles into the feedback signal means that some of the spectral noise shaping information is removed. There is therefore inevitably a reduction in the SNR that is achievable by the modulator. For example, in the situation where the control signal is of the form of waveform D of FIG. 12 and waveform C of FIG. 13, there is a situation where a quarter of the signal being fed back into the modulator is replaced with transition-cycles. In other words, only 75% of the feedback signal comprises noise shaping content while the remaining 25% comprises gain scaling (and offset) content. Therefore, for a gain of 6 dB (a factor of 2), the SNR degradation is 2.5 dB (a factor of approximately 1.3).

A sigma-delta modulator having an improved noise performance is illustrated in FIG. 14.

As explained above, the allowable input range of a sigma-delta modulator is determined by the upper and lower voltages of the feedback signal. In one embodiment, the upper and lower voltages of the feedback signal are set by two boundary voltages. The feedback signal is formed by using the digital output signal to select between the two boundary voltages. The implied gain and offset of the sigma-delta modulator is controlled by selecting appropriate values for the boundary voltages.

A sigma-delta modulator in which effective gain and offset are controlled by setting boundary voltages is illustrated in FIG. 14. The modulator comprises a summation unit 1401, an integrator 1402, a quantizer 1403 and a selection circuit 1404 connected in a feedback loop.

The summation unit is arranged to receive an analog input signal and an adjustment signal, which is output by the selection circuit. The summation unit subtracts the adjustment signal from the analog input signal and outputs the subtracted signal to the integrator. The integrator filters the subtracted signal and outputs the filtered signal to the quantizer, which compares the integrated signal to a reference signal in the comparator. If the output signal from the integrator is greater than the reference signal, a ‘one’ is output, and if the integrator output signal is less than the reference signal, a ‘zero’ is output. Thus, the analog input signal has been converted into a digital output signal.

The modulator outputs the digital output signal. The digital output signal is also fed back to the selection circuit. The role of the selection circuit is to set the input range of the sigma-delta modulator via the adjustment signal.

The selection circuit shown in FIG. 14 comprises a multiplexer 1405, a first DAC 1406, a second DAC 1407 and a control unit 1408. The multiplexer receives as inputs the digital output signal and two boundary values. Each boundary value is a voltage output from a respective one of the two DACs. The first DAC outputs a first boundary value and the second DAC outputs a second boundary value. The voltage output by each DAC is controlled by a control signal generated by the control unit. The control unit is therefore able to control the boundary values input into the multiplexer via the two control signals.

The control unit may be implemented in software. The control signals generated by the control unit may be digital signals.

The digital output signal controls which of the two boundary values is output by the multiplexer at any given time. When the digital output signal is high (i.e. when the sigma-delta modulator is outputting a ‘one’), the multiplexer outputs one of the two boundary values. When the digital output signal is low (i.e. when the sigma-delta modulator is outputting a ‘zero’), the multiplexer outputs the other of the two boundary values. The adjustment signal output by the multiplexer therefore contains the same sequence of ones and zeros as the digital output signal, but with the voltage level of each ‘one’ and ‘zero’ in the digital output signal replaced by a respective one of the two boundary values. The upper and lower limits between which the adjustment signal varies can therefore be controlled by adjusting the two boundary values. In this way, the gain and offset applied to the analog input signal by the sigma-delta modulator can be directly controlled by the control unit.

A switch circuit may therefore advantageously use a sigma-delta modulator to receive an analog signal output from a series of switches, and low-pass filter that analog signal to remove the unwanted chatter frequencies and output a digital switch signal. That digital switch signal may then be received by, for example, a keyboard controller.

The digital output signal output from a sigma-delta modulator is a pulse-density modulated signal that represents the analog input signal as a bit stream of ones and zeros. The sigma-delta modulator in the switch circuit suitably low-pass filters the analog input signal. This results in a pulse-density modulated output signal in which the parts of the signal representative of the high frequency components of the analog input signal (resulting from contact bounce) are suppressed relative to the parts of the signal representative of the lower frequency components of the analog input signal (resulting from user-activation of the switch).

It should be understood that the first-order sigma-delta modulators as described above are only examples, and that this disclosure may be applied in other modulators. Any kind of sigma-delta modulator could be used, for example, analog, digital or switched capacitor. The loop filter has been shown specifically as an integrator. However, any loop filter that provides a modulator having a low pass frequency response with respect to the input signal could be used. Although the quantizer has been shown as a two-level type, it could have any number of levels. The method presented in the above disclosure is applicable to any order of modulator.

As described above, one application in which a sigma-delta modulator may be advantageously used as a debouncing circuit is in portable media players having a user input device involving a keypad located on a lead between the media player and a set of earphones. In such an application, a sigma-delta modulator can advantageously be used to generate a single digital output stream from multiple keys. In this way, only a single wire is needed to carry the digital signal representing the keyed input to the media player for processing. Alternatively, the user input device may itself contain a keyboard controller and so be able to issue commands according to the keyed inputs, for example, by sending a volume control circuit to the earphones.

Each sigma-delta modulator may receive an input signal generated by a single row in a scanned key matrix. Alternatively, the scanned key matrix may generate a single output stream indicative of the status of each of the switches in the matrix. This may be achieved by feeding each of the signals output by a row into a multiplexer that selects between analog signals output by each row of the matrix in turn to generate a single analog output signal. The multiplexer may be clocked at a faster rate than the sequential activation of the matrix columns, so that the multiplexer outputs the signal for each row during the time for which a single column is activated. The single output signal may then be input to the sigma-delta modulator for filtering and conversion into digital form.

Although a sigma-delta modulator may be advantageously used as a debouncing circuit for applications having multiple switches, a sigma-delta modulator may also be advantageously used in applications involving a single switch. A sigma-delta modulator provides a debouncing circuit that effectively removes chatter while providing a fast response. A sigma-delta modulator also provides the opportunity to implement effective gain and offset, as described above.

Although a debouncing circuit according to various embodiments has been described above with specific reference to an implementation in which the debouncing circuit is used in a user input of a portable media device, it should be understood that this is for the purposes of example only. The debouncing circuit of the various embodiments above may be advantageously used in any application in which switch debouncing is required.

The applicant hereby discloses in isolation each individual feature described herein and any combination of two or more such features, to the extent that such features or combinations are capable of being carried out based on the present specification as a whole in light of the common general knowledge of a person skilled in the art, irrespective of whether such features or combinations of features solve any problems disclosed herein, and without limitation to the scope of the claims. The applicant indicates that various embodiments may consist of any such feature or combination of features. In view of the foregoing description it will be evident to a person skilled in the art that various modifications may be made to the disclosure above.

1. A switch circuit comprising:
a mechanical switch having two contact elements, the switch being operable to bring the two contact elements into physical contact and thereby output an analog switch signal representative of operation of the switch; and
a sigma-delta modulator arranged to receive the analog switch signal and to output a digital switch signal in dependence thereon, the sigma-delta modulator having a frequency response such that it can suppress a relatively high frequency component of the analog input signal to debounce the output of the switch.

2. A switch circuit as claimed in claim 1, further comprising:
a plurality of mechanical switches, including the mechanical switch having two contact elements; and
wherein the switch circuit is arranged such that the analog switch signal received by the sigma-delta modulator is a single analog switch signal representative of the operation of each of the plurality of mechanical switches that is output from the plurality of mechanical switches.

3. A switch circuit as claimed in claim 2, wherein the plurality of mechanical switches is an array of switches extending in two dimensions, each switch being located on a row of the array in the first dimension and a column of the array in the second dimension and each row of the array being arranged to output the single analog switch signal as corresponding to operation of each of the switches located in that row.

4. A switch circuit as claimed in claim 3, wherein the switch circuit is arranged to sequentially activate each column of the array by applying an electric current to each column in turn, the instantaneous value of the single analog switch signal output by a row of the array as corresponding to operation of a switch located in the currently activated column of that row.

5. A switch circuit as claimed in claim 2, wherein the switch circuit is arranged such that operation of one of the plurality of mechanical switches causes the single analog switch signal to have a specific voltage level.

6. A switch circuit as claimed in claim 5, wherein the specific voltage level is the same irrespective of which one of the plurality of mechanical switches has been operated.

7. A switch circuit as claimed in claim 5, wherein the specific voltage level is dependent on which one of the plurality of mechanical switches has been operated.

8. A switch circuit as claimed in claim 7, wherein each of the plurality of mechanical switches located in a row of the array is associated with a specific voltage level such that operation of a switch in that row causes the single analog switch signal to have the specific voltage level associated with the operated switch.

9. A switch circuit as claimed in claim 8, wherein a row of the array comprises a potential divider and each switch located in that row is connected to a specific voltage level within the potential divider such that operation of a switch in that row causes the single analog switch signal to have the specific voltage level connected to the operated switch.

10. A switch circuit as claimed in claim 1, wherein the sigma-delta modulator comprises:
a summation unit to sum the analog switch signal with an adjustment signal to form a summation output signal;
an integrator arranged to receive the summation output signal and form an integrator output signal dependent thereon;
a quantizer arranged to receive the integrator output signal and form the digital switch signal dependent thereon; and
a feedback loop to generate the adjustment signal.

11. A switch circuit as claimed in claim 10, wherein the feedback loop comprises a digital-to-analog converter to receive the digital output signal and generate the adjustment signal in dependence thereon.

12. A switch circuit as claimed in claim 10, wherein the feedback loop comprises a logic circuit arranged to select between one of two predetermined values for the adjustment signal, the selection being performed in dependence on both the digital output signal and a control signal.

13. A switch circuit as claimed in claim 10, wherein the feedback loop comprises a selection circuit arranged to select between one of two boundary values for the adjustment signal, the selection being performed in dependence on the digital output signal.

14. A switch circuit as claimed in claim 1, wherein the sigma-delta modulator is configured to sample the analog input signal at a sampling rate that exceeds a maximum frequency of operation of the mechanical switch by a user.

15. A switch circuit as claimed in claim 14, wherein the sigma-delta modulator is arranged to sample the analog input signal at a sampling rate exceeding 20 Hz.

16. A switch circuit as claimed in claim 1, wherein the sigma-delta modulator is arranged to receive a clock signal of 5.12 kHz or above.

17. A switch circuit as claimed in claim 1, wherein the sigma-delta modulator is configured to low-pass filter the analog switch signal.

18. A switch circuit as claimed in claim 1, wherein the sigma-delta modulator has a frequency response suitable to suppress the relatively high frequency component of the analog input signal relative to a lower frequency component of the analog input signal corresponding to operation of the switch.

19. A debouncing method comprising:
receiving, at a sigma-delta modulator, an analog output of a mechanical switch; and
providing an output signal, corresponding to operation of the mechanical switch, from the sigma-delta modulator to debounce the analog output of the mechanical switch.

20. A switch circuit comprising:
means for bringing two contact elements of a mechanical switch into physical contact and thereby outputting an analog switch signal representative of operation of the switch; and
means for receiving the analog switch signal and outputting a digital switch signal in dependence thereon, the means for receiving having a frequency response such that it can suppress a relatively high frequency component of the analog input signal to debounce the output of the mechanical switch.

21. A switch circuit as claimed in claim 20, wherein the means for receiving the analog switch signal comprises:
means for summing the analog switch signal with an adjustment signal to form a summation output signal;
means for receiving the summation output signal and forming an integrator output signal dependent thereon;
means for receiving the integrator output signal and forming the digital switch signal dependent thereon; and
means for generating the adjustment signal.
